(19) United States
(12) Patent Application Publication
(10) Pub. No.: US 2006/0207086 A1
(43) Pub. Date: Sep. 21, 2006

(54) METHOD FOR LAMINATING CHIPS AND METHOD FOR MANUFACTURING SEMICONDUCTOR DEVICE USING THE SAME

(75) Inventor: Yoshihiro Saeki, Tokyo (JP)

Correspondence Address: STEVEN ROBERTS;SHINJYU GLOBAL IP, SOUTH FOREST BLDG., 11TH FLOOR, 1-4-19, MINAMIMORI-MACHI, KITA-KU, OSAKA, 530-0054, JP

(73) Assignee: OKI ELECTRIC INDUSTRY CO., LTD., Tokyo (JP)

(21) Appl. No.: 11/276,766

(22) Filed: Mar. 14, 2006

(30) Foreign Application Priority Data
Mar. 16, 2005 (JP) 2005/074356

(51) Int. Cl. H05K 3/36

(52) U.S. Cl. 29/830; 29/832

(57) ABSTRACT

A method for forming a laminated structure in which four or more chips are laminated together includes at least a step of laminating a first chip sub-block comprised of a plurality of laminated chips together with a second chip sub-block comprised of a plurality of laminated chips.

### BACKGROUND OF THE INVENTION

### FIELD OF THE INVENTION

The present invention relates to a method for laminating chips and a method for manufacturing a semiconductor device using the same, and in particular, relates to a modification in the lamination order of chips in a method for manufacturing a semiconductor device in which a plurality of chips are laminated together with flip chip technology.

A commonly used structure of a semiconductor device is described below, and is formed by laminating a plurality of chips in a plurality of layers (or stages) with flip chip technology. FIGS. 12A to 12C are vertical cross-section diagrams showing a heretofore known semiconductor device formed by laminating eight chips. As shown in FIG. 12A, a chip 1 is comprised of an IC chip 2, a plurality of bumps 3 that are allocated on one surface of the IC chip 2, and a plurality of chip ball pads 4-1 that are allocated on the other surface of the IC chip 2. Also, as shown in FIG. 12B, a substrate 5 has a plurality of substrate ball pads 4-2 on its upper surface. As shown in FIG. 12C, a plurality of chips 1 are laminated on the upper surface of a substrate 5. Here, a top layer chip 8 has a structure that is different from that of chips 1. Specifically, a plurality of bumps 3 are allocated on the lower surface of the top layer chip 8, but chip ball pads 4-1 are not allocated on the upper surface of the top layer 8. In addition, a resin 6 is filled in spaces between vertical adjacent chips 1, the space between the substrate 5 and a chip 1, and spaces located on the lateral sides of a laminated structure in which a plurality of chips 1 are laminated in a plurality of layers (or stages). Furthermore, a plurality of external terminals 7 are connected to the lower surface of the substrate 5.

Next, a method for manufacturing the above described heretofore known semiconductor device is hereinafter explained with reference to FIGS. 13A, 13B, 13C, 14A, and 14B. As shown in FIG. 13A, a first layer chip 1 (or a bottom layer chip 1) is laminated on a substrate 5 by connecting a plurality of bumps 3, which are allocated on the lower surface of the first layer chip 1, to a plurality of substrate ball pads 4-2, which are allocated on the upper surface of the substrate 5. Next, as shown in FIG. 13B, a second layer chip 1 is laminated on the first layer chip 1 by connecting a plurality of bumps 3, which are allocated on the lower surface of the second layer chip 1, to the plurality of chip ball pads 4-1, which are allocated on the upper surface of the first layer chip 1. As shown in FIG. 13C, the above described lamination steps are repeated in the same way. Thus, an eighth layer chip 8 (i.e., the top layer chip 8) is laminated on a seventh layer chip 1 by connecting a plurality of bumps 3, which are allocated on the lower surface of the eighth layer chip 8, to a plurality of chip ball pads 4-1, which are allocated on the upper surface of the seventh layer chip 1.

As a result, an eight-chip laminated structure is formed by sequentially laminating eight chips 1. Then, as shown in FIG. 14A, a resin 6 is filled in spaces between vertical adjacent chips 1, a space between the substrate 5 and the first layer chip 1, and spaces located on the lateral sides of the eight-chip laminated structure. As shown in FIG. 14B, a semiconductor device is manufactured by connecting a plurality of external terminals 7 to the lower side of the substrate 5.

Japan Patent Application Publication JP-A-2002-170919 (especially page 4 and FIG. 1) discloses another example of a heretofore known lamination method of semiconductor chips. This heretofore known method is a laminated packaging method for a semiconductor device, which is performed by sequentially laminating a plurality of semiconductor chips having solder. More specifically, this is a modified lamination method for a semiconductor device that is performed by sequentially laminating semiconductor chips. In this method, solder on opposing semiconductor chips is activated, and alignment of these opposing semiconductor chips is performed. Also, the opposing semiconductor chips are aligned, laminated and jointed by applying pressure without forming a solder joint layer. After the lamination joint of all the semiconductor chips is completed, a solder joint layer is formed by collectively applying heat to the semiconductor chip group. That is, this method is performed for the purpose of reducing the number of applications of heat with respect to the joints of the chips. However, this method is not performed in order to reduce the number of the applications of pressure.

However, the above described heretofore known manufacturing method has the following three problems. First, in the above described method, weight (i.e., pressure) and/or heat is applied in order to connect the bumps 3, which are allocated on an upper chip 1, to the chip ball pads 4-1, which are allocated on a lower chip 1. In other words, the application of weight and/or heat is conducted every time a plurality of chips 1 and the top layer chip 8 are sequentially laminated. Therefore, in specific terms, weight and/or heat is applied to the first layer chip 1 (i.e., the bottom layer chip 1) eight times, which corresponds to the number of lamination layers. On the other hand, weight and heat is applied the top layer chip 8 only once when that chip is laminated. Thus, the number of applications of weight and/or heat varies among the laminated chips. Therefore, the total amount of weight and/or heat applied varies among the laminated chips. For example, the difference in the number of applications of weight and/or heat is seven between the eighth layer chip 8 (i.e., the top layer chip 8) and the first layer chip 1 (i.e., the bottom layer chip 1). In general, there is a high possibility that the applications of weight and/or heat will influence chip properties. Therefore, if the ultimate total number of applications of weight and/or heat is different among the laminated chips, this causes variations (i.e., differences) in the properties of the laminated chips. As a result, a problem will be caused in which properties of a semiconductor device having a plurality of laminated chips cannot be properly obtained.

Second, as described above, the number of applications of weight and/or heat is different among the laminated chips. Therefore, the ultimate amount of weight and/or heat applied will be different among the laminated chips. In general, the shape of a bump is changed by the application of weight and/or heat. Because of this, the difference in the ultimate amount of weight and/or heat applied among the laminated chips can be the reason why the amount of change in the bumps of the laminated chips will vary. In other words, differences in the amount of changes in the bumps of the laminated chips will be caused. Therefore, the vertical distance between vertically adjacent chips will vary between the upper portion of the laminated chips and the lower portion of the laminated chips. A difference in the amount of mismatch in the thermal expansion rate, which is caused by temperature change in a semiconductor device, is caused by this difference in the vertical distance between the vertical adjacent chips. Furthermore, this difference will cause the concentration of stress, which is one of the reasons why a semiconductor device may become damaged.

Third, the number of applications of weight and/or heat to the first layer chip 1 (i.e., the bottom layer chip 1) at least corresponds to the number of laminated chips. Therefore, especially when a number of chips are laminated in a plurality of layers, a problem will be caused in which the first layer chip 1 (i.e., the bottom layer chip 1) and bumps 3 allocated on the chip 1 will be easily damaged.

In addition, the heretofore known method for laminating chips disclosed in Japan Patent Application Publication JP-A-2002-170919 is conducted by sequentially laminating a plurality of chips. Because of this, the lamination method disclosed in this publication has the above described three problems.

### SUMMARY OF THE INVENTION

It is therefore an object of the present invention to provide a method for laminating a plurality of chips, and a method for manufacturing a semiconductor device using the method for laminating a plurality of chips, which can reduce variations in the properties of each chip, and can accurately obtain semiconductor device properties, by reducing the differences in the total number of times that weight and/or heat is ultimately applied to each chip.

In addition, it is an object of the present invention to provide a method for laminating a plurality of chips, and a method for manufacturing a semiconductor device using the method for laminating a plurality of chips, which can avoid the concentration of stress, and prevent damage to a semiconductor device, by reducing the differences in the total number of times weight and/or heat is ultimately applied to the laminated chips, and by reducing the differences in the amount of deformation of the bumps formed on each of the laminated chips.

Furthermore, it is an object of the present invention to provide a method for laminating a plurality of chips, and a method for manufacturing a semiconductor device using the method for laminating a plurality of chips, which can prevent damage to a first layer chip (i.e., a bottom layer chip) and the bumps formed on the chip by reducing the number of times that weight and/or heat is applied to the first layer chip.

In accordance with a first aspect of the present invention, a method for forming a laminated structure in which four or more chips are laminated together comprises at least a step of laminating a first chip sub-block comprised of a plurality of laminated chips together with a second chip sub-block comprised of a plurality of laminated chips.

In accordance with a second aspect of the present invention, a method for manufacturing a semiconductor device that is comprised of a laminated structure in which four or more chips are laminated together comprises at least a step of laminating a first chip sub-block comprised of a plurality of laminated chips together with a second chip sub-block comprised of a plurality of laminated chips.

In accordance with a third aspect of the present invention, a method for manufacturing a semiconductor device that is comprised of a laminated structure in which three chips are laminated together comprises the steps of laminating a first chip on a support substrate, forming a first chip sub-block by laminating a second chip and a third chip together, and laminating the first chip sub-block on the first chip laminated on the support substrate.

In the present application, the term “chip” is not particularly limited to a semiconductor chip that is typified by an IC chip. It may be a type of chip that can be laminated, and a variety of chips are included herein. A ceramic capacitor chip, a sensor chip, a light-emitting element chip, and a light-receiving element chip can be suggested as typical examples of this chip type.

In addition, in the present application, the terms “multi-semiconductor chip laminated structure,” “multi-layer laminated structure,” and “laminated structure of a plurality of chips” mean a laminated structure that has a plurality of layers (or stages), each layer of which is comprised of a chip laminated in the vertical direction.

According to the present invention, the following three effects can be obtained. First, it will be possible to reduce the differences in the total number of times that weight and/or heat is applied to each of the laminated chips by forming a plurality of chip sub-blocks, each of which is comprised of a plurality of chips, without sequentially laminating chips, and by laminating the plurality of chip sub-blocks together. Because of this, the amount of weight and/or heat that is ultimately applied to each of the laminated chips will be substantially equalized amongst the laminated chips. Therefore, it will be possible to reduce the variations in the chip properties of the laminated chips by equalizing the total number of times that weight and/or heat are ultimately applied to each of the laminated chips. As a result, it will possible to accurately obtain semiconductor device properties in which a plurality of chips are laminated in a plurality of layers.

Second, it will be possible to reduce the differences in the number of times that weight and/or heat will be applied to each of the laminated chips, by forming a plurality of chip sub-blocks, each of which is comprised of a plurality of chips, without sequentially laminating the chips, and by laminating the plurality of chip sub-blocks together. Because of this, the amount of weight and/or heat applied will be substantially equalized amongst the laminated chips. Therefore, it is possible to reduce the differences in the amount of deformation in bumps formed on each of the laminated chips. Furthermore, spaces among the laminated chips will be substantially equalized, and it will be possible to reduce the differences in the amount of mismatch between the thermal expansion rate, which is caused by the temperature change in the semiconductor device. Because of this, it will be possible to prevent a semiconductor device from being damaged by effectively relieving the concentration of stress.

Third, it will be possible to greatly reduce the maximum number of times that weight and/or heat will be applied to each of the laminated chips by forming a plurality of chip sub-blocks, each of which is comprised of a plurality of chips, without sequentially laminating the chips, and by laminating the plurality of chip sub-blocks together. In particular, when a large number of chips are to be laminated together, the number of times that weight and/or heat will be applied thereto will be greatly decreased. Therefore, it is possible to effectively prevent chips and bumps formed on the chips from being damaged, even if a large number of chips are laminated together.

These and other objects, features, aspects, and advantages of the present invention will become apparent to those skilled in the art from the following detailed description, which, taken in conjunction with the annexed drawings, discloses a preferred embodiment of the present invention.

### BRIEF DESCRIPTION OF THE DRAWINGS

Referring now to the attached drawings which form a part of this original disclosure:

FIGS. 1A to 1D are vertical cross-section diagrams showing a manufacturing process of a resin-sealed semiconductor device having a multi-semiconductor chip laminated structure in accordance with a first embodiment of the present invention.

FIGS. 2A and 2B are vertical cross-section diagrams showing a manufacturing process of a resin-sealed semiconductor device having a multi-semiconductor chip laminated structure in accordance with the first embodiment of the present invention.

FIG. 3 is a vertical cross-section diagram showing a manufacturing process of a resin-sealed semiconductor device having a multi-semiconductor chip laminated structure in accordance with the first embodiment of the present invention.

FIGS. 4A to 4D are vertical cross-section diagrams showing a manufacturing process of a resin-sealed semiconductor device having a multi-semiconductor chip laminated structure in accordance with a second embodiment of the present invention.

FIGS. 5A and 5B are vertical cross-section diagrams showing a manufacturing process of a resin-sealed semiconductor device having a multi-semiconductor chip laminated structure in accordance with the second embodiment of the present invention.

FIG. 6 is a vertical cross-section diagram showing a manufacturing process of a resin-sealed semiconductor device having a multi-semiconductor chip laminated structure in accordance with the second embodiment of the present invention.

FIGS. 7A to 7D are vertical cross-section diagrams showing a manufacturing process of a resin-sealed semiconductor device having a multi-semiconductor chip laminated structure in accordance with a third embodiment of the present invention.

FIGS. 8A and 8B are vertical cross-section diagrams showing a manufacturing process of a resin-sealed semiconductor device having a multi-semiconductor chip laminated structure in accordance with the third embodiment of the present invention.

FIG. 9 is a vertical cross-section diagram showing a manufacturing process of a resin-sealed semiconductor device having a multi-semiconductor chip laminated structure in accordance with the third embodiment of the present invention.

FIG. 10 is a vertical cross-section diagram showing a hollow package structure having a multi-semiconductor chip laminated structure to which a lamination method in accordance with the present invention is applied.

FIG. 11 is a vertical cross-section diagram showing a hollow package structure having a multi-semiconductor chip laminated structure to which a lamination method in accordance with the present invention is applied.

FIGS. 12A to 12C are vertical cross-section diagrams showing a typical example of a semiconductor device formed by laminating eight chips.

FIGS. 13A to 13C are vertical cross-section diagrams showing a heretofore known method for manufacturing the semiconductor device shown in FIGS. 12A to 12C.

FIGS. 14A and 14B are vertical cross-section diagrams showing a heretofore known method for manufacturing the semiconductor device shown in FIGS. 12A to 12C.

### DETAILED DESCRIPTION OF THE PREFERRED EMBODIMENTS

Selected embodiments of the present invention will now be explained with reference to the drawings. It will be apparent to those skilled in the art from this disclosure that the following descriptions of the embodiments of the present invention are provided for illustration only and not for the purpose of limiting the invention as defined by the appended claims and their equivalents.

Referring now to the drawings, preferred embodiments of the present invention will be described in detail.

### First Embodiment

When the number of lamination layers is an n-th power of two and n is an integer of two or more

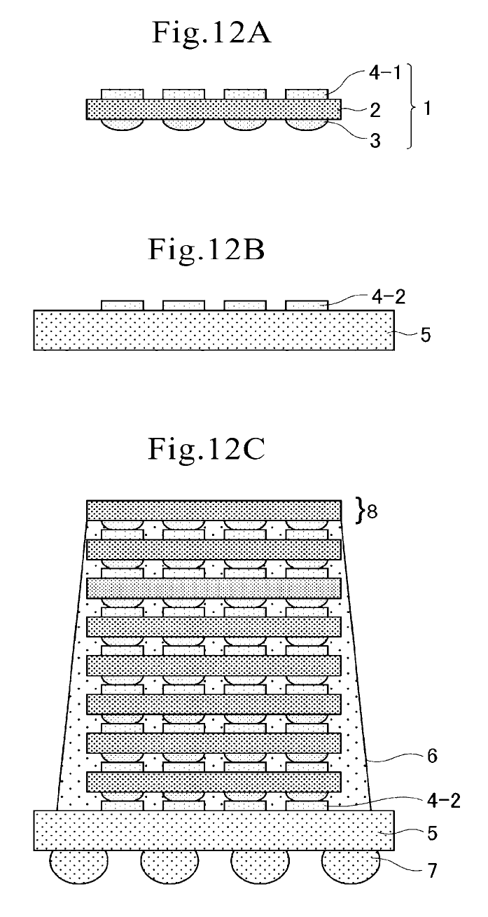

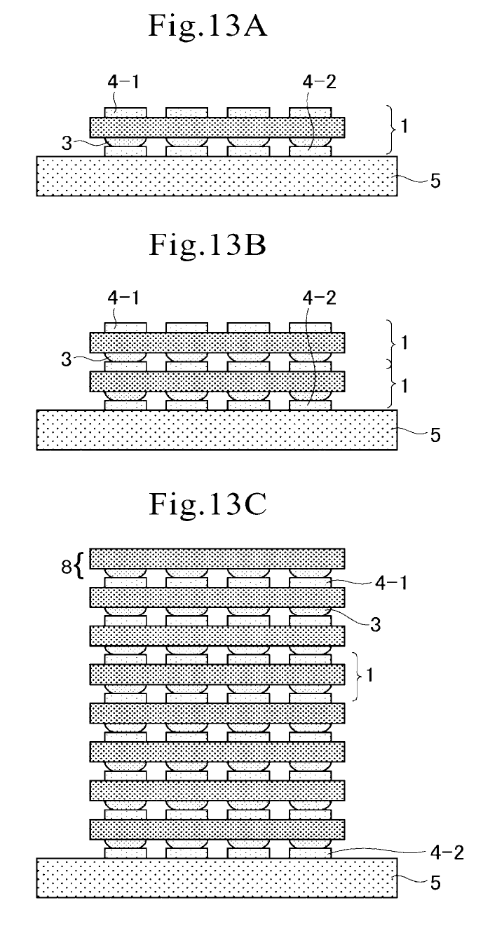

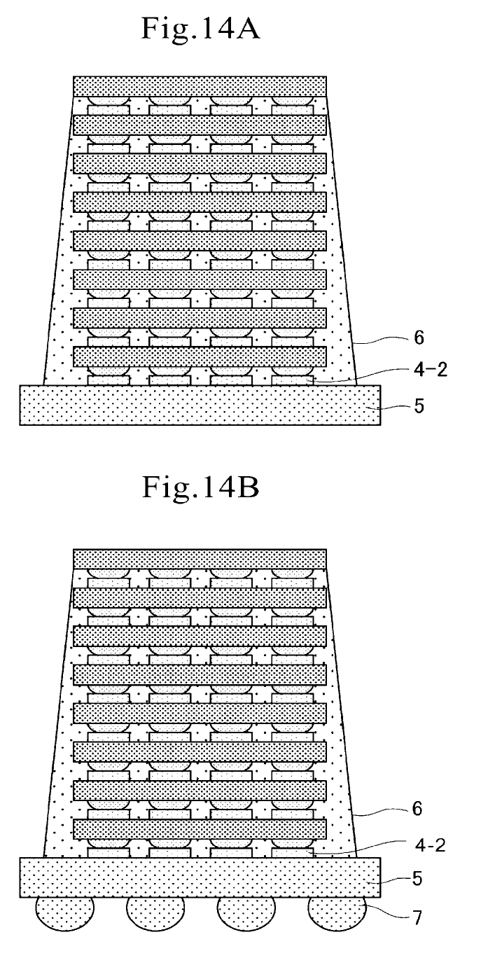

In the first embodiment of the present invention, a method for manufacturing a laminated structure in which a plurality of semiconductor chips are laminated is provided. However, the “structure” of a finished semiconductor device with this laminated structure is not an improved version of the structure of heretofore known semiconductor devices. In other words, “a method” for manufacturing a semiconductor device with this laminated structure in accordance with the first embodiment of the present invention is different from that of the heretofore known semiconductor devices with this laminated structure. Therefore, in order to clarify the difference between them, the method for manufacturing the laminated structure in accordance with the first embodiment of the present invention is hereinafter explained by taking a semiconductor device having a structure identical to a semiconductor device manufactured using the above described heretofore known technology, as an example. That is, the semiconductor device in accordance with the first embodiment of the present invention has a structure shown in FIG. 12C. The semiconductor device shown in FIG. 12C is formed by laminating eight chips (i.e., seven chips 1 and a top layer chip 8) on a substrate 5. A plurality of chip ball pads 4-1 are allocated on the upper surfaces of each of the seven chips 1, except for the top layer chip 8 (i.e., the eighth layer chip 8), and a plurality of bumps 3 are allocated on the lower surface of each of the seven chips 1 and the top layer chip 8. That is, a plurality of bumps 3 are allocated on the lower surface of the eighth layer chip 8, but no chip ball pads 4-1 are formed on the upper surface of the eighth layer chip 8. Also, a resin 6 is filled in the space between the substrate 5 and the first layer chip 1 (i.e., the bottom layer chip 1), the spaces between vertically adjacent chips 1, and the spaces located on the lateral sides of a laminated structure comprised of a plurality of the chips 1. In addition, a plurality of external terminals 7 are connected to the lower surface of the substance 5.

Lamination Process

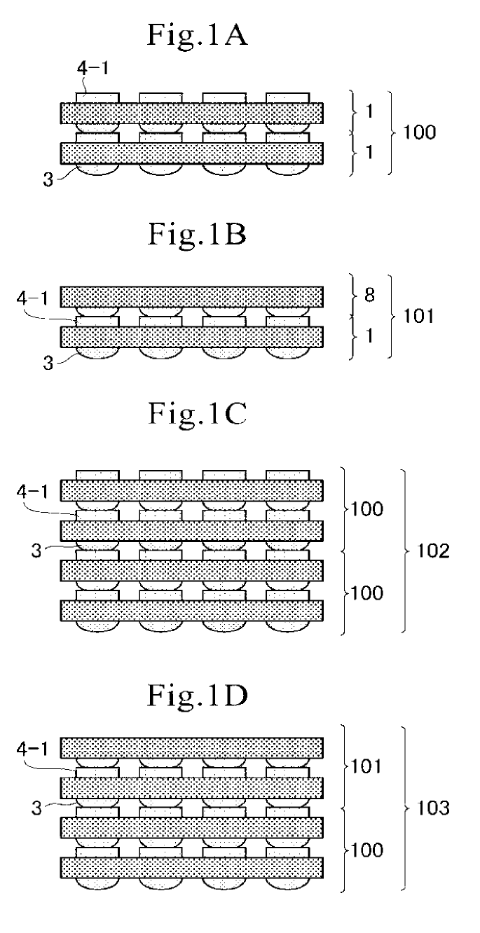

FIGS. 1A, 1B, 1C, 1D, 2A, 2B, and 3 are vertical cross-section diagrams showing a manufacturing process of a semiconductor device having a multi-layer laminated structure composed of a plurality of semiconductor chips in accordance with the first embodiment of the present invention. As shown in FIG. 1A, a chip 1 has a plurality of bumps 3 on one surface and a plurality of chip ball pads 4-1 on the other surface. As shown in FIG. 1B, a top layer chip 8 has a plurality of bumps 3 on one surface but does not have any chip ball pads 4-1. In the first embodiment of the present invention, seven chips 1 and the top layer chip 8 are prepared, and the following lamination process is conducted by using these chips as basic components.

As shown in FIG. 1A, a first-type two-chip sub-block 100 is formed by laminating two chips 1. A total of three first-type two-chip sub-blocks 100 are formed. On the other hand, as shown in FIG. 1B, a second-type two-chip sub-block 101 is formed by laminating the top layer chip 8 on a chip 1. As shown in FIG. 1C, a first-type four-chip sub-block 102 is formed by laminating two first-type two-chip sub-blocks 100. On the other hand, as shown in FIG. 1D, a second-type four-chip sub-block 103 is formed by laminating the second-type two-chip sub-block 101 on the first-type two-chip sub-block 100.

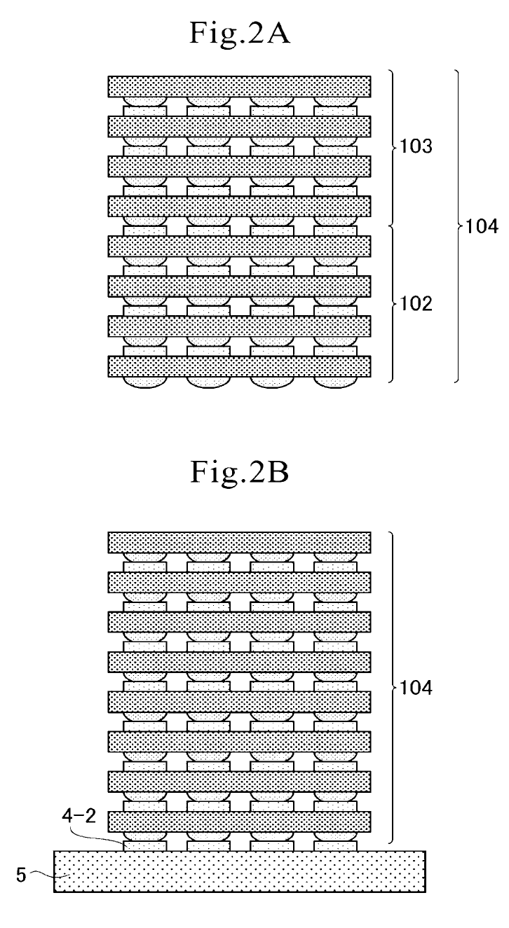

As shown in FIG. 2A, an eight-chip block 104 is formed by laminating the second-type four-chip sub-block 103 on the first-type four-chip sub-block 102. Here, the above described heretofore known method can be applied as a specific chip lamination method. More specifically, when chips are laminated, the bumps 3 formed on an upper chip are connected to the chip ball pads 4-1 formed on a lower chip by applying weight (i.e., pressure) and/or heat. As shown in FIG. 2B, the eight-chip block 104 is mounted on a substrate 5. In other words, the eight-chip block 104 is mounted on the substrate 5 by connecting the bumps 3 formed on the first layer chip 1 (i.e., the bottom layer chip 1) of the eight-chip block 104 to the substrate ball pads 4-2 formed on the upper surface of the substrate 5 by applying weight and/or heat.

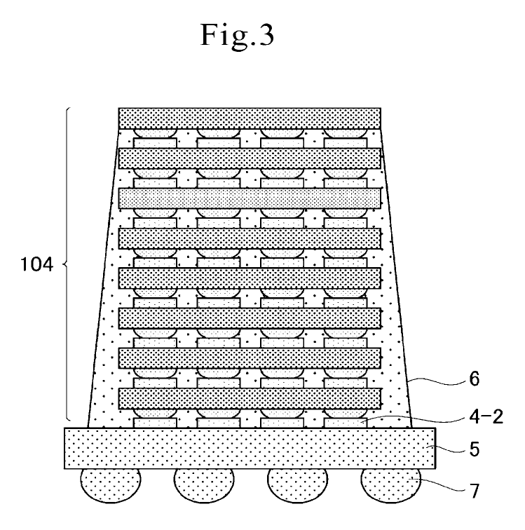

As shown in FIG. 3, a resin 6 is filled into the spaces between vertically adjacent chips 1 in the eight-chip block 104, the space between the substrate 5 and the first layer chip 1 (i.e., the bottom layer chip 1), and the spaces located on the lateral sides of the eight-chip block 104. Here, the resin 6 can be applied and filled with a heretofore known method, such as a method which uses a dispenser. Furthermore, a plurality of external terminals 7 are connected to the lower surface of the substrate 5, and a semiconductor device is manufactured thereby.

According to the first embodiment of the present invention, a total of four two-chip sub-blocks, each of which is comprised of a laminated structure of two chips, is formed without sequentially laminating chips one by one. Then, two four-chip sub-blocks are formed by further laminating two two-chip sub-blocks, respectively. Next, the eight-chip block is formed by laminating these two four-chip sub-blocks. Therefore, in this phase, only three lamination steps are conducted with respect to all the chips. Finally, the eight-chip block is mounted on the substrate. Therefore, weight and/or heat is applied to all the chips four times by conducting four lamination steps. In other words, the number of times that weight and/or heat is applied will be completely equalized amongst all the laminated chips. Also, the number of times that weight and/or heat will be applied to the first layer chip (i.e., the bottom layer chip) can be reduced to four times. As a result, the following three effects can be obtained.

First, the number of times that weight and/or heat will be applied to each of the laminated chips will be equalized among all the laminated chips. Because of this, the number of times that weight and/or heat is ultimately applied to each of the laminated chips is completely equalized amongst all the laminated chips. In other words, variations in the properties of the laminated chips will not be caused because the total number of times that weight and/or heat are applied to each of the laminated chips is equalized amongst all the laminated chips. As a result, it is possible to accurately obtain semiconductor device properties in which a plurality of chips are laminated.

Second, as described above, the number of times that weight and/or heat is ultimately applied to each of the laminated chips will be equalized amongst all the laminated chips, because the number of times that weight and/or heat will be applied to each of the laminated chips will be equalized amongst all the laminated chips. In general, applications of weight and/or heat change the shape of bumps formed on a chip. However, differences in the amount of deformation in the bumps will not be caused amongst all the laminated chips, because the number of times that weight and/or heat will be applied to each of the laminated chips is equalized amongst all the laminated chips. Because of this, the spaces (i.e., the vertical distance) between vertically adjacent laminated chips will be equalized, and thus differences in the amount of mismatch in the thermal expansion rate, which results from the temperature change in a semiconductor device, will not be caused. Therefore, it will be possible to prevent a semiconductor device from becoming damaged by effectively avoiding the concentration of stress.

Third, the number of times that weight and/or heat will be applied to the first layer chip (i.e., the bottom layer chip) will be greatly reduced, compared to the number of times that weight and/or heat are applied in the heretofore known method. Specifically, it will reduced from eight times to four times. Because of this, especially when a large number of chips are to be laminated together, the number of times that weight and/or heat will be applied will be greatly decreased. Therefore, it will be possible to effectively prevent the first layer chip (i.e., the bottom layer chip) and bumps formed on this chip from being damaged, even if a large number of chips are laminated together.

Alterative Lamination Process

As described above, in the first embodiment of the present invention, for the purpose of completely equalizing the number of times that weight (i.e., pressure) and/or heat is applied to the laminated chips, a laminated structure comprised of an eight-chip block is formed by laminating two four-chip sub-blocks, and then this laminated structure is mounted on a support substrate. However, the present invention is not necessarily limited to this example. For example, either of the two four-chip sub-blocks may be mounted on the support substrate, and then the other four-chip sub-block may be laminated on the four-chip sub-block mounted on the support substrate. In this case, there is a difference in the number of times that weight and/or heat will be applied to each of the laminated chips between the chips included in the upper four-chip sub-block and the chips included in the lower four-chip sub-block. That is, the difference in the number of times that weight and/or heat will be applied to each of the laminated chips is one between the chips included in the upper four-chip sub-block and the chips included in the lower four-chip sub-block. However, the number of times that weight and/or heat will be applied to each of the chips included in the upper four-chip sub-block can be reduced from four times to three times.

Alternative Number of Lamination Layers

In the first embodiment of the present invention, the eight-chip laminated structure is explained. However, the present invention is not necessarily limited to the eight-chip laminated structure, and it can be applied to a structure having three or more laminated chips (i.e., three or more layers of chips). On the other hand, the present invention cannot be applied to a structure having two or less laminated chips. Also, if the number of the laminated chips is the n-th power of two, the number of times that weight (i.e., pressure) and/or heat will be applied to each of the laminated chips will be completely equalized amongst all the laminated chips. Therefore, variations in the properties of the laminated chips will not be caused. In other words, the above described first effect can be obtained. In addition, the concentration of stress can be effectively avoided. In other words, the above described second effect can be obtained. Furthermore, if the number of the laminated chips is eight, the number of times that weight and/or heat will be applied can be reduced to four. In addition, if the number of laminated chips is 16, the number of times that weight and/or heat will be applied will be reduced to five. Therefore, as the number of the laminated chips increases, the number of times that weight and/or heat is applied will be effectively decreased. In other words, the above described third effect can be obtained.

In the first embodiment of the present invention, a laminated structure is described in which the number of lamination layers is the n-th power of two (here, n is an integer equal or greater than two). However, the present invention is not necessarily limited to this case. For example, the present invention can be effectively applied to a laminated structure in which four or more even-numbered chips are laminated together (and the even number is not an n-th power of two), and a laminated structure in which five or more odd-numbered chips are laminated together. When the number of lamination layers is an even number equal to or greater than four but is not an n-th power of two

Lamination Process

The present invention can be effectively applied to a laminated structure in which even-numbered chips are laminated (and the even number is not an n-th power of two). First, prepared chips are paired together, and a plurality of two-chip sub-blocks are formed by laminating two chips, respectively. If the number of the two-chip sub-blocks formed is an even number, for example, six, all six of the two-chip sub-blocks are paired together, and three four-chip sub-blocks are formed by laminating two two-chip sub-blocks together, respectively. Then, an eight-chip sub-block is formed by laminating two of the three four-chip sub-blocks, and the remaining four-chip sub-block is laminated on this eight-chip sub-block. Thus, it is possible to form a twelve-chip block.

On the other hand, if the number of two-chip sub-blocks formed is an odd number, for example, five, four of the five two-chip sub-blocks may be paired together, and two four-chip sub-blocks may be formed by laminating two two-chip sub-blocks, respectively. Then, an eight-chip sub-block may be formed by laminating two four-chip sub-blocks, and a ten-chip block may be formed by laminating this eight-chip sub-block and the remaining two-chip sub-block. In addition, a six-chip sub-block may be formed by laminating one of the two four-chip sub-blocks and the above described remaining two-chip sub-block, and then a ten-chip block may be formed by laminating this six-chip sub-block and the above described remaining four-chip sub-block.

According to the present invention, even if the number of lamination layers is an even number and is not an n-th power of two, for example, ten or twelve, the above described three effects can be obtained.

First, the difference in the number of times that weight (i.e., pressure) and/or heat is applied to each of the laminated chips can be reduced to one amongst all the laminated chips. Because of this, the number of times that weight and/or heat will be applied to each of the laminated chips will be substantially equalized amongst all the laminated chips. Therefore, variations in the properties of the laminated chips can be reduced. As a result, it is possible to accurately obtain semiconductor device properties in which a plurality of chips are laminated in a plurality of layers. Thus, the above described first effect can be obtained.

In addition, the difference in the number of times that weight and/or heat will be applied to each of the laminated chips can be reduced to one. Because of this, the number of times that weight and/or heat will be ultimately applied to each of the laminated chips will be substantially equalized amongst the laminated chips. Therefore, it is possible to reduce the differences in the amount of deformation in the bumps amongst all the laminated chips. In other words, the spaces (i.e., the vertical distance) between vertically adjacent chips in the laminated structure will be substantially equalized, and thus it will be possible to reduce the differences in the amount of mismatch in the thermal expansion rate, which is caused by temperature change in a semiconductor device. Because of this, it is possible to effectively relieve the concentration of stress and to prevent the semiconductor device from being damaged. Thus, the above described second effect can be obtained.

In addition, the number of times that weight and/or heat is applied to each of the laminated chips will be greatly reduced to up to a maximum of five times when a ten-chip laminated structure or a twelve-chip laminated structure is formed. In particular, when a large number of chips are laminated, the number of times that weight and/or heat are applied to each of the laminated chips will be greatly decreased. Therefore, it is possible to effectively prevent chips or bumps formed on these chips from being damaged even if a large number of chips are laminated in a plurality of layers. Thus, the above described third effect can be obtained.

Alternative Number of Lamination Layers

As described above, a chip lamination process in which four or more even-numbered chips are formed (and the even number is not an n-th power of two) was explained as a typical example. In this process, the finished laminated structure is formed by completing all the steps of the lamination process, and then it is mounted on the support substrate. However, the lamination process is not necessarily limited to this example. For example, in the middle of the lamination process, a chip sub-block may be mounted on the support substrate, and the remaining chip sub-blocks may be laminated on this chip sub-block mounted on the support substrate.

More specifically, in the case of a ten-chip laminated structure, the prepared chips are paired together, and five two-chip sub-blocks are formed by laminating two chips, respectively. Then, four two-chip sub-blocks are paired together, and two four-chip sub-blocks are formed by laminating two two-chip sub-blocks together, respectively. Furthermore, a six-chip sub-block is formed by laminating the remaining two-chip sub-block and either of the two four-chip sub-blocks together. Finally, a ten-chip block is formed by laminating this six-chip sub-block and the remaining four-chip sub-block together. Thus, a laminated structure comprised of the ten-chip block is formed. After this step, this laminated structure may be mounted on a support substrate.

In addition, instead of this lamination process, the following process may be used. First, the prepared chips are paired together, and five two-chip sub-blocks are formed by laminating two chips together, respectively. Then, four two-chip sub-blocks are paired together, and two four-chip sub-blocks are formed by laminating two two-chip sub-blocks together. Then, a six-chip sub-block is formed by laminating either of the two four-chip sub-blocks and the remaining two-chip sub-block together. On the other hand, the remaining four-chip sub-block of the two four-chip sub-blocks is mounted on the support substrate. Then, the six-chip sub-block is laminated on this four-chip sub-block mounted on the support substrate. Thus, a 10-chip block is formed on the support substrate.

Furthermore, in the case of forming a twelve-chip laminated structure, the following lamination process may be used. First, the prepared chips are paired, and six two-chip sub-blocks are formed by laminating two chips together, respectively. Then, six two-chip sub-blocks are paired, and three four-chip sub-blocks are formed by laminating two two-chip sub-blocks together, respectively. Next, two of the three four-chip sub-blocks are paired, and an eight-chip sub-block is formed by laminating these two four-chip sub-blocks together. Then, a laminated structure comprised of a twelve-chip block is formed by laminating the remaining four-chip sub-block on this eight-chip sub-block. Finally, this laminated structure is mounted on the support substrate. In addition, the following lamination process may be used. First, all the prepared chips are paired, and six two-chip sub-blocks are formed by laminating two chips, respectively. Then, six two-chip sub-blocks are paired, and three four-chip sub-blocks are formed by laminating two two-chip sub-blocks together, respectively. Next, two of the three four-chip sub-blocks are paired, and an eight-chip sub-block is formed by laminating these two four-chip sub-blocks together. Then, the remaining four-chip sub-block may be mounted on the support substrate. Furthermore, the eight-chip sub-block may be mounted on the four-chip sub-block mounted on the support substrate. It is also possible to obtain the above described three effects by these types of the lamination process.

When the Number of Lamination Layers is an Odd Number Equal to or Greater than Five

Lamination Process

The present invention can be effectively applied to a laminated structure in which five or more odd-numbered chips are laminated. Here, a laminated structure in which nine chips are laminated will be explained as an example. First, eight of nine prepared chips are paired together, and four two-chip sub-blocks are formed by laminating two chips together, respectively. Then, the four two-chip sub-blocks are paired, and two four-chip sub-blocks are formed by laminating the two two-chip sub-blocks together. Next, an eight-chip sub-block is formed by laminating the two four-chip sub-blocks together. Then, a laminated structure comprised of a nine-chip block is formed by laminating the remaining chip, which is not paired in the previous lamination step, on the eight-chip sub-block. Finally, this laminated structure is mounted on a support substrate.

In this case, when the number of times that weight (i.e., pressure) and/or heat is applied to the ninth layer chip (i.e., the top layer chip to be laminated in the final lamination step) and the number of times that weight and/or heat are applied to the other laminated chips are compared, the difference in the number of times that weight and/or heat is applied will be three. However, this difference in the number of times that weight and/or heat is applied between the chip laminated last and the other laminated chips is sufficiently small, compared to the heretofore known methods.

However, when it is desirable to inhibit variation in the number of times that weight and/or heat is applied to each of the laminated chips, the following lamination process may be used.

First, eight of nine prepared chips are paired together, and four two-chip sub-blocks are formed by laminating two chips together, respectively. Then, a three-chip sub-block is formed by laminating one of the four two-chip sub-blocks together with the remaining chip that is not paired in the previous lamination step. Next, a four-chip sub-block is formed by laminating two of the remaining three two-chip sub-blocks together. Then, a five-chip sub-block is formed by laminating the remaining two-chip sub-block and the three-chip sub-block together. Finally, a laminated structure comprised of a nine-chip block is formed by laminating the four-chip sub-block and the five-chip sub-block together. Then, this laminated structure may be mounted on a support substrate.

In this case, the number of times that weight and/or heat is applied to each of the laminated chips is four or five. Therefore, the difference in the number of times that weight and/or heat is applied to each of the laminated chips can be reduced to one. Thus, it is possible to obtain the above described three effects by these types of lamination processes.

First, the difference in the number of times that weight and/or heat is applied to each of the laminated chips can be reduced to one. Therefore, the number of times that weight and/or heat is ultimately applied to each of the laminated chips will be substantially equalized amongst all the laminated chips. Because of this, it will be possible to reduce variations in the chip properties amongst all the laminated chips. As a result, it is possible to accurately obtain semiconductor device properties in which a plurality of chips are laminated in a plurality of layers. Thus, it is possible to obtain the above described first effect.

Second, the difference in the number of times that weight and/or heat is applied to each of the laminated chips can be reduced to one. Therefore, the number of times that weight and/or heat is ultimately applied to each of the laminated chips will be substantially equalized amongst all the laminated chips. Therefore, it is possible to reduce the difference in the amount of deformation in the bumps formed on the chips. Because of this, the spaces (i.e., the vertical distance) between vertically adjacent chips in the laminated structure will be equalized, and it will be possible to reduce the differences in the amount of mismatch in the thermal expansion rate that is caused by the temperature change in the semiconductor device. As a result, the concentration of stress can be effectively relieved, and it will be possible to prevent the semiconductor device from being damaged. Thus, it will be possible to obtain the above described second effect.

Third, the number of times that weight and/or heat is applied to each of the laminated chips will be greatly reduced to a maximum of five times. In particular, when a large number of chips are laminated, the number of times that weight and/or heat are applied to each of the laminated chips will be greatly decreased. Therefore, it is possible to effectively prevent chips and bumps formed on these chips from being damaged, even if a large number of chips are laminated in a plurality of layers. Thus, it will be possible to obtain the above described third effect.

When the Number of Lamination Layers is Three

Lamination Process

The present invention can be effectively applied to a laminated structure in which three chips are laminated together in three layers. In this case, one of three prepared chips is mounted on a support substrate, and a two-chip sub-block is formed by laminating the remaining two chips together with each other. Then, a semiconductor device comprised of a three-chip block can be formed by laminating this two-chip sub-block on the chip mounted on the support substrate.

In this case, the number of times that weight (i.e., pressure) and/or heat is applied to each of the laminated chips is two. Therefore, at least the following three effects can be obtained.

First, the number of times that weight and/or heat is applied to each of the laminated chips will be equalized amongst all the laminated chips. Therefore, the number of times that weight and/or heat is ultimately applied to each of the laminated chips will be completely equalized amongst all the laminated chips. In other words, the total number of times that weight and/or heat is applied to each of the laminated chips will be equalized amongst all the laminated chips, and thus variation in the chip properties will not be caused. As a result, it will be possible to accurately obtain semiconductor device properties in which a plurality of chips are laminated in a plurality of layers.

Second, as described above, the number of times that weight and/or heat is applied to each of the laminated chips will be completely equalized amongst all the laminated chips. Therefore, the number of times that weight and/or heat is ultimately applied to each of the laminated chips will be equalized amongst all the laminated chips. In general, bumps formed on the chips will be deformed by applications of weight and/or heat. However, in this case, the total number of applications of weight and/or heat to each of the laminated chips will be equalized amongst all the laminated chips. Therefore, differences in the amount of deformation in the bumps formed on the chips will not be caused. Because of this, the spaces (i.e., the vertical distance) between vertically adjacent chips in the laminated structure will be equalized, and thus differences in the amount of mismatch in the thermal expansion rate that is caused by the temperature change in the semiconductor device will not be caused. As a result, the concentration of stress can be effectively avoided and thus it will be possible to prevent the semiconductor device from being damaged.

Third, when the number of times that weight and/or heat is applied to the first layer chip (i.e., the bottom layer chip) in this lamination process is compared with that in the heretofore known lamination process, the number of times that weight and/or heat is applied in this lamination process is reduced from three to two. Therefore, it is possible to effectively prevent the first layer chip (i.e., the bottom layer chip) and bumps formed in this chip from being damaged.

Alternative Lamination Process

In the above described example, the lamination process to form the laminated structure in which five or more odd-numbered chips are laminated together was described as a typical example. In this lamination process, the finished laminated structure is formed by conducting all the steps of the lamination process and this finished laminated structure is mounted on the support substrate. However, this lamination process is not necessarily limited to the above described example. For example, in the middle of the lamination process, a chip sub-block or a chip may be mounted on the support substrate, and the remaining chip sub-block may be laminated on the chip sub-block or the chip.

More specifically, if the number of the laminated chips is nine, eight of prepared nine chips are paired, and four two-chip sub-blocks are formed by laminating two chips, respectively. Then, a three-chip sub-block is formed by laminating one of the four two-chip sub-blocks and the remaining chip that is not paired in the previous lamination step. Next, a four-chip sub-block is formed by laminating two of the remaining three two-chip sub-blocks, and a five-chip sub-block is formed by laminating the remaining two-chip sub-block and the three-chip sub-block. Finally, the four-chip sub-block may be mounted on the support substrate, and then the five-chip sub-block may be laminated on the four-chip sub-block mounted on the support substrate. In addition, the five-chip sub-block may be mounted on the support substrate, and then the four-chip sub-block may be mounted on the five-chip sub-block mounted on the support substrate. In this case, the number of times that weight (i.e., pressure) and/or heat is applied to each of the laminated chips is four or five. Therefore, the difference in the number of times that weight and/or heat is applied to each of the laminated chips can be reduced to one. Thus, the number of times that weight and/or heat is applied to some of the laminated chips can be reduced to a minimum of four. Therefore, the above described three effects can be obtained in these types of the lamination process.

### Second Embodiment

In the above described first embodiment of the present invention, a resin is filled into the spaces after a laminated structure is mounted on a support substrate. However, the step of filling the resin into the spaces is not necessarily limited to this example. For example, it is possible to conduct the following steps. In the second embodiment of the present invention, a liquid resin is applied to substantially the whole surface of one side of a chip before conducting a chip lamination process. Then, chips are laminated together, and heat and pressure is applied to them. For example, thermocompression bonding can be conducted. Thus it is possible to simultaneously conduct the formation of a resin that seals the spaces between the chips and the lamination of the chips. Referring now to the drawings, the second invention will be described in detail.

Lamination Process

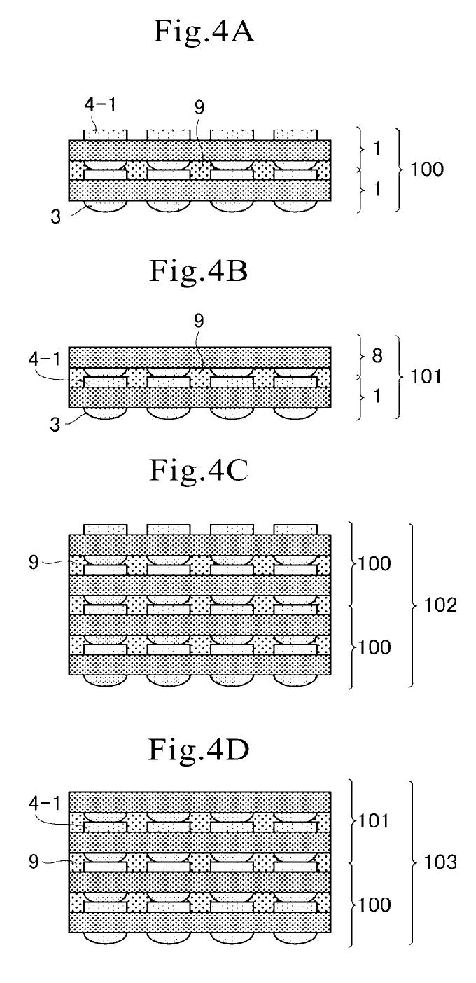

FIGS. 4A, 4B, 4C, 4D, 5A, 5B, and 6 are vertical cross-section diagrams showing a manufacturing process of a semiconductor device having a multi-layer laminated structure of a plurality of semiconductor chips in accordance with the second embodiment of the present invention. As shown in FIG. 4A, a chip 1 has a plurality of bumps 3 on one surface and a plurality of chip ball pads 4-1 on the other surface. As shown in FIG. 4B, a top layer chip 8 has a plurality of bumps 3 on one surface but does not have any chip ball pads 4-1. In the second embodiment of the present invention, seven chips 1 and the top layer chip 8 are prepared, and the following lamination process is conducted by using these chips as basic components.

As shown in FIG. 4A, a resin 9 is applied to the entire upper surface (i.e., the surface in which the plurality of the chip ball pads 4-1 are formed) of a chip 1, and a first-type two-chip sub-block 100 is formed by laminating two chips 1 together. As described above, in the first embodiment of the present invention, a resin is applied after the laminated structure is formed. However, in the second embodiment of the present invention, the resin 9 is applied during the chip lamination process. In other words, a resin 9 is applied before forming a chip sub-block by laminating the chips together. Therefore, the resin is hereinafter called a first-in resin 9. A total of three first-type two-chip sub-blocks 100 are formed. On the other hand, as shown in FIG. 4B, the first-in resin 9 is applied to the entire upper surface (i.e., the surface in which the plurality of the chip ball pads 4-1 are formed) of a chip 1, and a second-type two-chip sub-block 101 to which the first-in resin 9 is applied is formed by laminating the top layer chip 8 on the chip 1.

As shown in FIG. 4C, the first-in resin 9 is applied to the entire upper surface (i.e., the surface in which the plurality of chip ball pads 4-1 are formed) of a first-type two-chip sub-block 100, and a first-type four-chip sub-block 102 to which the first-in resin 9 is applied is formed by laminating two first-type two-chip sub-blocks 100. On the other hand, as shown in FIG. 4D, the first-in resin 9 is applied to the entire upper surface (i.e., the surface in which the plurality of the chip ball pads 4-1 are formed) of a first-type two-chip sub-block 100, and a second-type four-chip sub-block 103 to which the first-in resin 9 is applied is formed by laminating the second-type two-chip sub-block 101 on the first-type two-chip sub-block 100.

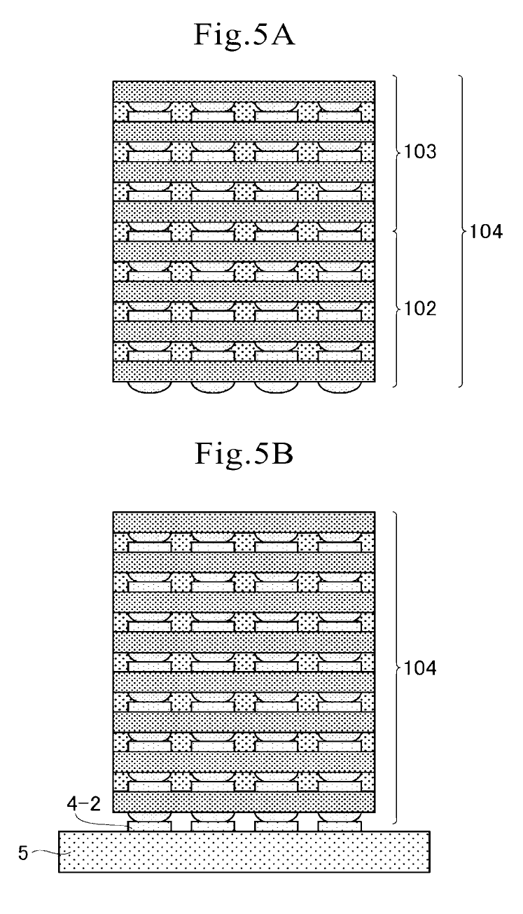

As shown in FIG. 5A, the first-in resin 9 is applied to the entire upper surface (i.e., the surface in which the plurality of chip ball pads 4-1 are formed) of the first-type four-chip sub-block 102, and an eight-chip block 104 to which the first-in resin 9 is applied is formed by laminating the second-type four-chip sub-block 103 on the first-type four-chip sub-block 102. Here, the above described heretofore known method can be applied as a specific chip lamination method. More specifically, when chips are laminated together, the bumps 3 formed on an upper chip are connected to the chip ball pads 4-1 formed on a lower chip by applying weight (i.e., pressure) and/or heat. As shown in FIG. 5B, the eight-chip block 104 to which the first-in resin 9 is applied is mounted on a substrate 5. In other words, the eight-chip block 104 is mounted on the substrate 5 by connecting the bumps 3 formed on the first layer chip 1 (i.e., the bottom layer chip 1) of the eight-chip block 104 to the substrate ball pads 4-2 formed on the upper surface of the substrate 5 with the application of weight and/or heat.

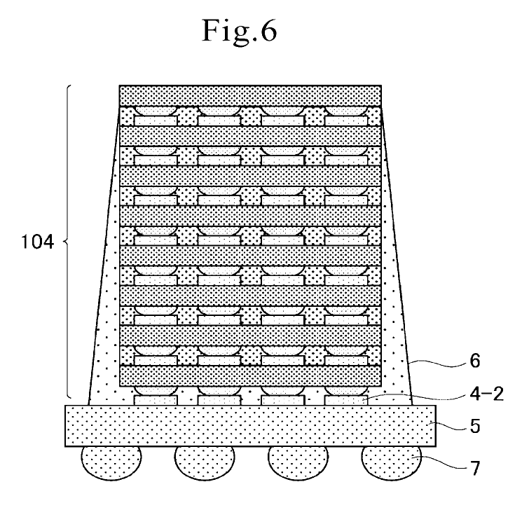

As shown in FIG. 6, a resin 6 is filled in the space between the substrate 5 and the first layer chip 1 (i.e., the bottom layer chip 1) of the eight-chip block 104, and the spaces located on the lateral sides of the eight-chip block 104. Here, the resin 6 can be applied and filled with a heretofore known method, such as a method using a dispenser. Furthermore, a plurality of external terminals 7 are connected to the lower surface of the substrate 5, and a semiconductor device is manufactured thereby.

As described above, the second embodiment of the present invention is different from the first embodiment of the present invention in that the first-in resin 9 is applied to the entire upper surface of a chip before laminating the chips, and in that the first-in resin 9 is also applied to the entire upper surface of a chip sub-block before laminating the chip sub-blocks. However, except for this difference, the other lamination steps in the second embodiment of the present invention are identical to those in the first embodiment of the present invention. Therefore, it is possible for the second embodiment of the present invention to obtain the above described three effects of the first embodiment of the present invention.

Furthermore, according to the second embodiment of the present invention, it is possible to prevent the bumps 3 formed on a chip from being damaged when laminating the chips and/or chip sub-blocks, because the chips and/or chip sub-blocks are fixed by applying the first-in resin 9 to the entire upper surface of a chip and/or a chip sub-block before conducting lamination steps. In addition to the first to third effects of the above described first embodiment of the present invention, this effect is hereinafter referred to as a fourth effect.

In addition, according to the second embodiment of the present invention, formation of a resin that seals the spaces between chips, and the lamination of the chips, can be simultaneously conducted in the same step, because a liquid resin is applied to substantially the entire upper surface of a chip before laminating the chips, and then the chips are laminated and heat and pressure are applied to them. In addition to the first to fourth effects, this effect is hereinafter referred to as a fifth effect.

### Third Embodiment

In the above described second embodiment of the present invention, the first-in resin 9 is applied to the entire upper surface of a chip and/or a chip sub-block, and the chips and/or sub-chip-blocks are laminated. However, the first-in resin 9 is not necessarily applied to the entire upper surface of a chip and/or a chip sub-block in order to prevent bumps 3 formed on a chip from being damaged in the lamination process of the chips and/or chip sub-blocks. For example, the first-in resin 9 may be applied to only a portion of the upper surface of a chip and/or a chip sub-block, preferably a center portion of the upper surface of a chip and/or a chip sub-block. Referring now to the drawings, the third embodiment will be described in detail.

Lamination Process

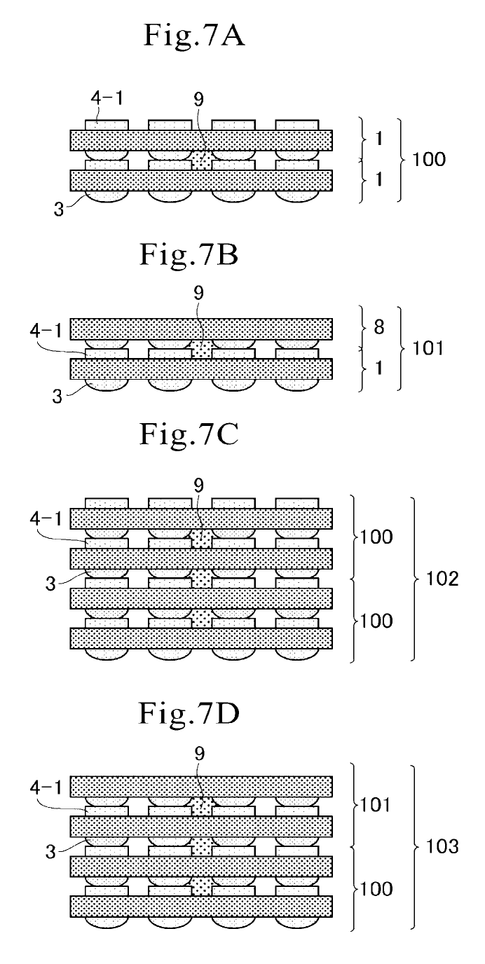

FIGS. 7A, 7B, 7C, 7D, 8A, 8B, and 9 are vertical cross-section diagrams showing a manufacturing process of a semiconductor device having a multi-layer laminated structure of a plurality of semiconductor chips in accordance with the third embodiment of the present invention.

As shown in FIG. 7A, a chip 1 has a plurality of bumps 3 on one surface and a plurality of chip ball pads 4-1 on the other surface. As shown in FIG. 7B, a top layer chip 8 has a plurality of bumps 3 on one surface but does not have any chip ball pads 4-1. In the third embodiment of the present invention, seven chips 1 and the top layer chip 8 are prepared, and the following lamination process is conducted by using these chips as basic components.

A shown in FIG. 7A, a resin 9 is applied to only the center portion of the upper surface (i.e., the surface in which the plurality of the chip ball pads 4-1 are formed) of a chip 1, and a first-type two-chip sub-block 100 to which the first-in resin 9 is applied is formed by laminating two chips 1 together. A total of three first-type two-chip sub-blocks 100 are formed. On the other hand, as shown in FIG. 7B, the first-in resin 9 is applied to the center portion of the upper surface (i.e., the surface in which the plurality of the chip ball pads 4-1 are formed) of a chip 1, and a second-type two-chip sub-block 101 to which the first-in resin 9 is applied is formed by laminating the top layer chip 8 on the chip 1.

As shown in FIG. 7C, the first-in resin 9 is applied to only the center portion of the upper surface (i.e., the surface in which the plurality of chip ball pads 4-1 are formed) of a first-type two-chip sub-block 100, and a first-type four-chip sub-block 102 to which the first-in resin 9 is applied is formed by laminating two first-type two-chip sub-blocks 100. On the other hand, as shown in FIG. 7D, the first-in resin 9 is applied to only the center portion of the upper surface (i.e., the surface in which the plurality of the chip ball pads 4-1 are formed) of a first-type two-chip sub-block 100, and a second-type four-chip sub-block 103 to which the first-in resin 9 is applied is formed by laminating the second-type two-chip sub-block 101 on the first-type two-chip sub-block 100.

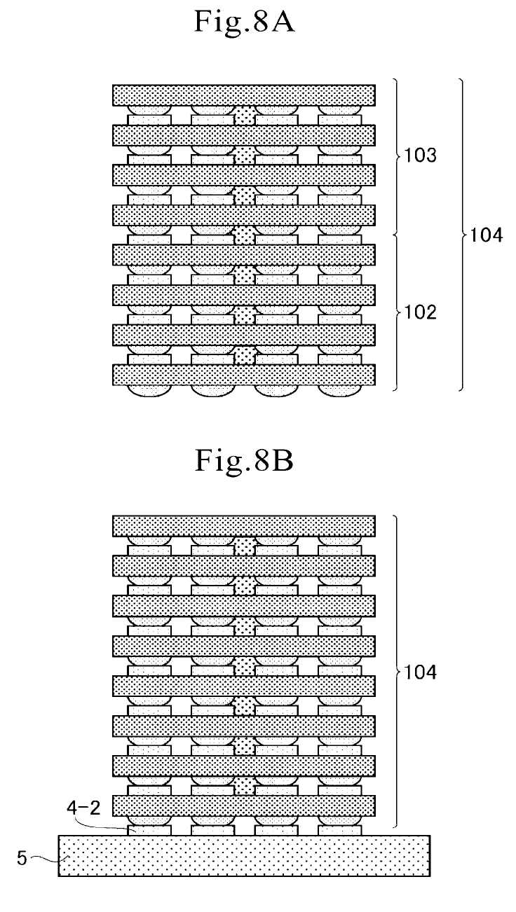

As shown in FIG. 8A, the first-in resin 9 is applied to only the center portion of the upper surface (i.e., the surface in which the plurality of chip ball pads 4-1 are formed) of the first-type four-chip sub-block 102, and an eight-chip block 104 to which the first-in resin 9 is applied is formed by laminating the second-type four-chip sub-block 103 on the first-type four-chip sub-block 102. Here, the above described heretofore known method can be applied as a specific chip lamination method. More specifically, when chips are laminated, the bumps 3 formed on an upper chip are connected to the chip ball pads 4-1 formed on a lower chip by applying weight (i.e., pressure) and/or heat. As shown in FIG. 8B, the eight-chip block 104 to which the first-in resin 9 is applied is mounted on a substrate 5. In other words, the eight-chip block 104 is mounted on the substrate 5 by connecting the bumps 3 formed on the first layer chip 1 (i.e., the bottom layer chip 1) of the eight-chip block 104 to the substrate ball pads 4-2 formed on the upper surface of the substrate 5 with the application of weight and/or heat.

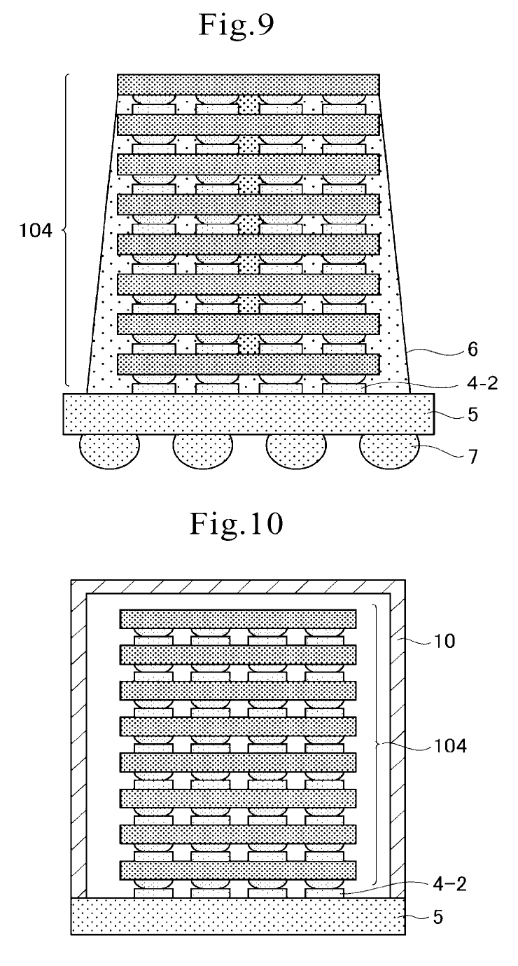

As shown in FIG. 9, a resin 6 is filled in the spaces between chips comprising the eight-chip block 104 other than the spaces where the first-in resin 9 was applied (i.e., spaces between chips comprising the eight-chip block 104 except for the center portions of those chips filled by the first-in resin 9), the space between the substrate 5 and the first layer chip 1 (i.e., the bottom layer chip 1) of the eight-chip block 104, and the spaces located on the lateral sides of the eight-chip block 104. Here, the resin 6 can be applied and filled with a heretofore known method, such as a method using a dispenser. Furthermore, a plurality of external terminals 7 are connected to the lower surface of the substrate 5, and a semiconductor device is manufactured thereby.

As described above, the third embodiment of the present invention is different from the second embodiment of the present invention in that the first-in resin 9 is applied to only the center portion of the upper surface of a chip before lamination, and in that the first-in resin 9 is also applied to only the center portion of the upper surface of a chip sub-block before laminating chip sub-blocks. However, except for this difference, the other lamination steps in the third embodiment of the present invention are identical to those in the second embodiment of the present invention. Therefore, it is possible for the third embodiment of the present invention to obtain the above described five effects of the second embodiment of the present invention.

As described above, in the second embodiment of the present invention, the first-in resin 9 is applied to the entire upper surface of a chip and a chip sub-block. However, there is a possibility that the liquid first-in resin 9 will flow out of the spaces between adjacent chips in the later steps of applying heat and pressure in the lamination process. Therefore, there is a possibility that the following problem will be caused. That is, the protruding portion of the liquid first-in resin 9 will move to the upper surface of an upper chip of adjacent chips and to the lower surface of a lower chip of adjacent chips through the lateral sides of the adjacent chips, and further adhere to the chip ball pads 4-2 allocated on the upper surface of the upper chip of the adjacent chips and to the bumps allocated on the lower surface of the lower chip.

On the other hand, if the first-in resin 9 is applied to only the center portion of a chip and that of a chip sub-block as described in the third embodiment of the present invention, the following sixth effect can be obtained. That is, it is possible to prevent the first-in resin 9 applied to the center portion of a chip and/or a chip sub-block from flowing out of the spaces between adjacent chips, moving to the upper surface of an upper chip of the adjacent chips and to the lower surface of a lower chip of the adjacent chips, and adhering to the chip ball pads 4-2 allocated on the upper surface of the upper chip of the adjacent chips and to the bumps 3 allocated on the lower surface of the lower chip of the adjacent chips, even if the first-in resin 9 is spread out in the center when applying heat and pressure in the lamination process of chips. In addition, if the first-in resin 9 is applied to only the center portion of a chip and that of a chip sub-block as described in the third embodiment of the present invention, the fourth effect described in the second embodiment of the present invention can be obtained, which it is possible for bumps 3 formed on a chip from being damaged in the chip lamination process.

Furthermore, as an alternative method, the first-in resin 9 may be selectively applied to a portion of the upper surface of a chip and/or a chip sub-block except for the frame portion of the upper surface of the chip and/or the chip sub-block. In this case, the first-in resin 9 can be prevented from flowing out of the spaces between adjacent chips even if it spreads out in the areas where it is applied. In addition, in this case, the bumps 3 formed on a chip can be prevented from being damaged in the chip lamination process.

### Alternative Embodiment

In the above described embodiments, the present invention is applied to the case in which semiconductor chips typified by an IC chip are laminated as a typical example. However, the object to be laminated is not necessarily limited to a semiconductor chip, and it may be any chip type that can be laminated. For example, a variety of chips, such as a ceramic capacitor chip, a sensor chip, a light-emitting element chip, and a light-receiving element chip, can be included in this chip type.

In addition, as described above, the present invention can be applied to the case in which a plurality of chips are comprised of the same material. However, application of the present invention is not necessarily limited to this case. For example, the present invention also can be applied to the case in which a plurality of chips are comprised of materials different from each other are laminated together.

Moreover, in the above described embodiments, the bumps 3 are formed on one surface of a chip, and chips are laminated by keeping the surface on which the bumps 3 are allocated down. However, as an alternative example, it is possible to apply the present invention to the case in which the bumps 3 are allocated on one surface of a chip, and chips are laminated by keeping the surface on which the bumps 3 are allocated up. Furthermore, it is possible to apply the present invention to the case in which bumps 3 are allocated on both surfaces of a chip, and chips are laminated with the surfaces on which bumps 3 are allocated facing each other.

Furthermore, in the above described embodiments, the step of bonding chips is conducted by the application of both weight (i.e., pressure) and heat. However, the method of bonding chips is not necessarily limited to this method, so long as the chips can bonded with each other. Therefore, a heretofore known method can be applied to bonding of chips. For example, the bonding of the chips may be conducted only by the application of weight. Also, the bonding of the chips may be conducted only by the application of heat. In addition, the bonding of the chips may be conducted by the application of supersonic waves. Furthermore, the bonding of the chips may be conducted by the combined application of weight, heat, and supersonic waves.

In addition, in the above described embodiment, the laminated chip structure is mounted on the upper surface of the support substrate, and then the external terminals are formed on the lower surface of the support substrate. However, as an alternative example, the laminated chip structure may be mounted on the upper surface of the support substrate after the external terminals are formed on the lower surface of the support substrate.

Furthermore, in the above described embodiments, the present invention is applied to a method for manufacturing a semiconductor device comprised of a laminated structure mounted on a support substrate. However, the present invention is not necessarily applied to this case. For example, the present invention can be applied to any method that includes a process of forming a laminated structure in which a variety of chips are laminated in a plurality of layers. Also, in the above described embodiments, the laminated structure is mounted on the support substrate on which external terminals are formed. However, it is possible to use a chip in which the external connection function is performed with wafer level chip size package (W-CSP) technology as a substrate. In other words, the present invention also can be applied to a method for forming a laminated structure without a support substrate.

In addition, in the above described embodiment, the laminated structure is sealed by filling a liquid resin into the spaces therein. It is possible to use heretofore known methods, such as a method using a dispenser in order to apply the liquid resin. Also, in the formation process of a laminated structure, a liquid thermoset resin may be applied and it may be partially hardened by a thermal pretreatment. Then, the partially hardened thermoset resin may be completely hardened by a final heat treatment after a laminated structure is mounted on a support substrate.

Furthermore, a film resin (i.e., a sheet resin) in which openings are formed in the positions corresponding to the positions of chip ball pads may be allocated in spaces between the chips instead of a liquid resin. Then, a laminated structure may be sealed and isolated by cutting this film resin at the same time as the chips are cut in a later step.

In addition, it is possible to use a hollow package, typified by a ceramic hollow package, without conducting resin sealing. For example, as shown in FIG. 10, a hollow package can be formed by putting a cup-shaped lid 10 whose height is taller than that of a laminated structure 104 on a support substrate 5 to cover the laminated structure 104.

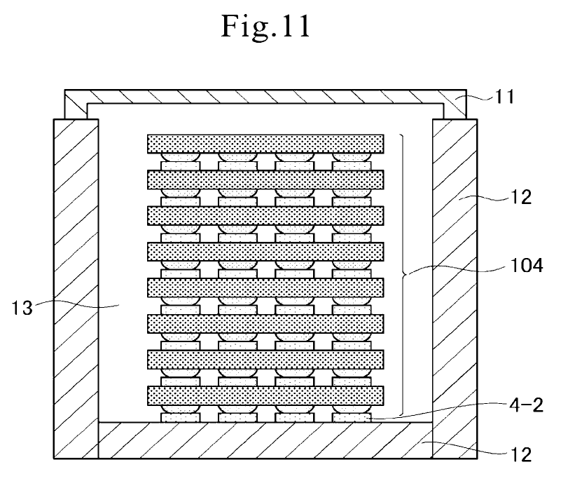

Furthermore, as shown in FIG. 11, another type of a hollow package can be formed. In this case, a support substrate 12 that has a cavity 13 whose height is the same with or more than that of a laminated structure 104 is used instead of a flat support substrate. The laminated structure 104 is mounted inside the cavity 13, and then a flat lid 11 is put on the support substrate 12 to cover the cavity 13.

This application claims priority to Japanese Patent Application No. 2005-074356. The entire disclosure of Japanese Patent Application No. 2005-074356 hereby incorporated herein by reference.

The terms of degree, such as “substantially,” used herein mean a reasonable amount of deviation of the modified term such that the end result is not significantly changed. For example, the terms can be construed as including a deviation of at least ±5% of the modified term if this deviation would not negate the meaning of the word it modifies.

While only selected embodiments have been chosen to illustrate the present invention, it will be apparent to those skilled in the art from this disclosure that various changes and modifications can be made herein without departing from the scope of the invention as defined in the appended claims. Furthermore, the foregoing descriptions of the embodiments according to the present invention are provided for illustration only, and not for the purpose of limiting the invention as defined by the appended claims and their equivalents. Thus, the scope of the invention is not limited to the disclosed embodiments.

What is claimed is:

1. A method for forming a laminated structure in which four or more chips are laminated together, comprising the step of laminating a first chip sub-block comprised of a plurality of laminated chips together with a second chip sub-block comprised of a plurality of laminated chips.

2. The method according to claim 1, further comprising the step of forming a laminated structure comprised of a final chip block by laminating the first chip sub-block and the second chip sub-block as a final lamination step.

3. The method according to claim 1, wherein at least either the first chip sub-block or the second chip sub-block is formed by laminating a third chip sub-block comprised of a plurality of laminated chips together with a fourth chip sub-block comprised of a plurality of laminated chips.

4. The method according to claim 1, wherein at least either the first chip sub-block or a second chip sub-block is formed by laminating a third chip sub-block comprised of a plurality of laminated chips together with a single chip.

5. The method according to claim 1,
wherein the number of laminated layers in the laminated structure is an even number equal to or greater than four; and
further comprising a first step in which all chips are paired together, and a plurality of two-chip sub-blocks are formed by laminating the paired chips together.

6. The method according to claim 1,
wherein the number of laminated layers in the laminated structure is an odd number equal to or greater than five; and
further comprising a first step in which all chips except for one chip are paired together, and a plurality of two-chip sub-blocks are formed by laminating the paired chips together.

7. The method according to claim 1, further comprising the step of applying a liquid resin to at least a portion of one surface of the chip before conducting each of the lamination steps.

8. The method according to claim 1, further comprising the step of applying a film resin to at least one surface of the chip before conducting each of the lamination steps.

9. A method for forming a laminated structure formed by laminating together an even number of chips equal to or greater than four, comprising the steps of:
forming a plurality of two-chip sub-blocks by pairing all chips together, and laminating the paired chips together; and
forming a final chip block by laminating a first chip sub-block comprised of a plurality of laminated chips together with a second chip sub-block comprised of a plurality of laminated chips, at least either the first chip sub-block or the second chip sub-block formed by laminating a third chip sub-block comprised of a plurality of laminated chips together with a fourth chip sub-block comprised of a plurality of laminated chips.

10. A method for forming a laminated structure formed by laminating together an odd number of chips equal to or greater than five, comprising the steps of:
forming a plurality of two-chip sub-blocks by paring all chips together except for one chip, and by laminating the paired chips together.
forming a final chip block by laminating a first chip sub-block comprised of a plurality of laminated chips together with a second chip sub-block comprised of a plurality of laminated chips, at least either the first chip sub-block or the second chip sub-block formed by laminating a third chip sub-block comprised of a plurality of laminated chips together with a single chip.
